(19) United States
(12) Patent Application Publication
(10) Pub. No.: US 2005/0001314 A1
(43) Pub. Date: Jan. 6, 2005

(54) Semiconductor device

(76) Inventors: Naotaka Tanaka, Chiyoda (JP); Tomio Iwasaki, Tsukuba (JP); Hideo Miura, Sendai (JP); Yasuyuki Nakajima, Tachikawa (JP); Tomoo Matsuzawa, Tokyo (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/873,251

(22) Filed: Jun. 23, 2004

(30) Foreign Application Priority Data
Jun. 24, 2003 (JP) 2003-178990

(51) Int. Cl. H01L 21/44

(52) U.S. Cl. 257/738

(57) ABSTRACT

An object of the present invention is to establish, for an LSI having a stacked interconnection structure of Cu interconnect/Low-k material, a narrow pitch wire bonding technique enabling a reduction in damage to a bonding pad and application similar to the conventional LSI of an aluminum interconnection. In a semiconductor device having a multilayer interconnection made of a Cu interconnect/Low-k dielectric material, the above-described object can be attained by a bonding pad structure in which all the wiring layers up to the uppermost cap interconnect are formed of a Cu wiring layer and a bonding pad portion formed of a Cu layer is equipped with a refractory intermediate metal layer such as Ti (titanium) filmor (tungsten) film on the Cu layer and an aluminum alloy layer on the intermediate metal layer.

### CLAIM OF PRIORITY

The present application claims priority from Japanese application serial no. 2003-178990, filed on Jun. 24, 2003, the content of which is hereby incorporated by reference into this application.

### FIELD OF THE INVENTION

The present invention relates to a semiconductor device.

### BACKGROUND OF THE INVENTION

Aluminum alloy interconnects have been used for connecting between semiconductor elements in conventional semiconductor devices and they are electrically connected to the outside via a connecting member such as bonding wire. In Japanese Patent Laid-Open No. H5 (1993)-6915 (Patent Document 1), disclosed is an invention for suppressing a deterioration in the soundness of connection of such a connecting member. According to the proposal by this invention, in an electrode pad portion for connecting a bonding wire on a semiconductor substrate covered with a insulating film, the insulating film is formed of an SiO film or phosphosilicate glass (PSG) and the electrode pad has a three layer structure having an Al film as the bottom layer, a Ti compound film as the intermediate layer and an Al film as the upper layer, whereby peeling between the insulating film and the Ti compound is prevented. [Patent Document] Japanese Patent Laid-Open No. H5(1993)-6915

A multilayer interconnect having this aluminum alloy film as a main layer of the interconnect is formed on a semiconductor element and this multilayer interconnect has a barrier metal film as a bottom layer and a cap metal film as an upper layer, with the aluminum alloy film therebetween. The barrier metal film is formed in order to prevent mutual diffusion of, for example, Si from the silicon substrate and aluminum from the aluminum alloy film. The final layer of this multilayer interconnect obtained by successively stacking the barrier metal film, aluminum alloy and cap metal film is used as a bonding pad (external terminal).

A wire is bonded to this bonding pad via a bonding opening formed in a final insulating film (final protective film) which covers the surface of the bonding pad. The wire is usually a gold wire. This bonding pad portion is formed by removing the upper cap metal film with the bonding opening as a mask. The cap metal film is removed for the purpose of improving bondability between the bonding pad and the wire.

The raw material for the above-described barrier metal film has varied, depending on the generation of a metallization process, but in semiconductors, especially, semiconductor products using miniaturization process, a barrier film made of a Ti compound composed of titanium (Ti) or titanium nitride (TiN) can be used for improving contact properties and preventing disconnection of aluminum interconnects due to stress migration The Ti compound is however inferior in adhesion with the underlying insulating film such as SiO or phosphosilicate glass (PSG) so that peeling occurs between the Ti compound and underlying insulating film due to the stress upon wire bonding. Stable film adhesion is therefore aimed at as in the above-described known example.

When a multilayer interconnection is formed using a Cu interconnect and a low dielectric constant dielectric material in combination, the modulus of elasticity of low dielectric constant dielectric material (dielectric constant: 1 to 3.5), which is generally called “Low-k material”, lowers to about ⅕ to 1/20 of that of SiO (dielectric constant: 4 or greater). In this case, therefore, it is necessary to attain narrow-pitch wire bonding to a rigid bonding pad portion formed on an underlying dielectric material much softer than the conventional product. No countermeasure against it is disclosed in the above-described known example.

### SUMMARY OF THE INVENTION

An object of the present invention is to provide a semiconductor device having a Cu interconnect, which causes less damage to an external connection pad or a member around it, and exhibits less deterioration in the connection of an external connection member.

The present invention is able to have the following modes in order to overcome the above-described problem.

This makes it possible to provide a semiconductor device equipped with a multilayer interconnection structure made of a Cu/Low-k material, which causes less damage to an external connection pad portion (for example, bonding pad) or members around the portion and exhibits less deterioration in bonding property compared with LSI having an aluminum interconnect.

(1) A semiconductor device equipped with an external connection pad portion which is connected to a wiring layer composed mainly of copper and is electrically connected to the outside, is characterized in that the wiring layer is formed on a first interlayer insulating film having a dielectric constant lower than that of SiO, a second interlayer insulating film is formed on the wiring layer, the external connection pad portion is formed on the second interlayer insulating film, the external connection pad has a first layer and a second layer formed thereon, and that the second layer has a modulus of elasticity higher than that of the first layer.

More specifically, the bonding pad portion is equipped with a first layer electrically connected to the wiring layer, a second layer formed on the first layer, and a third layer formed between the first layer and the second layer. The third layer has a modulus of elasticity higher than that of each of the first layer and the second layer and the first layer has a modulus of elasticity higher than that of the second layer.

(2) In a semiconductor device, at the pad portion, the first layer is thicker than that of the second layer.

(3) A semiconductor device comprises a semiconductor substrate, a semiconductor element formed thereon, a first insulating film layer formed on the semiconductor element, a first wiring layer formed on the first insulating film layer and being composed mainly of copper, a second interlayer insulating film formed on the first wiring layer, a bonding wiring layer formed on the second interlayer insulating film and electrically connected to the first wiring layer via a plug formed in the second interlayer insulating film, and a bonding pad portion which is formed in the bonding wiring layer and is to have an external connection terminal bonded thereto. In the semiconductor device, the first interlayer insulating film has a dielectric constant lower than that of SiO, the bonding wiring layer is composed mainly of copper, and at the bonding pad portion, an intermediate layer is formed on the bonding wiring layer, and a bonding layer composed mainly of aluminum is formed on the intermediate layer.

The intermediate layer further contains, for example, titanium tungsten, or titanium nitride.

For example, a bonding wire for electrical connection to the outside is bonded to the bonding pad portion.

The second interlayer insulating film has a dielectric constant lower than that of SiO.

In the above-described semiconductor device, it is preferred to adjust the aspect ratio of a bonding height of bump to a bonding diameter of bump to ⅖ or greater but not greater than ½ upon wire bonding with a gold wire.

(4) A semiconductor device comprises a semiconductor substrate, a semiconductor element formed thereon, a first insulating film layer formed on the semiconductor element, a first wiring layer formed on the first insulating film layer and being composed mainly of copper, a second interlayer insulating film formed on the first wiring layer, a bonding wiring layer formed on the second interlayer insulating film and electrically connected to the first interconnect via a plug formed in the second interlayer insulating film, a wire bonding pad portion formed in the bonding wiring layer, and a bonding wire bonded to the bonding pad portion and electrically connected to the outside. In a plurality of the above-described structures of the device, some bonding wires are bonded at a ratio of a bonding height (thickness) of bump to a bonding diameter of bump falling within a range of ⅕ or greater but less than ⅖ and some are bonded at the ratio falling within a range of ⅖ or greater but not greater than ½; and at the same time, more than half of the bonding wires are bonded at the ratio falling within a range of ⅖ or greater but not greater than ½.

(5) A semiconductor package comprises a semiconductor device equipped with any one of the above-described modes, a substrate on which an LSI is to be mounted or a lead frame, and a bonding wire for electrically connecting the bonding pad portion of the semiconductor device and the substrate or lead frame, and further comprises a molding resin for sealing the bonding wire.

It is, for example, a semiconductor package in which at least one LSI having the above-described bonding pad structure has been mounted onto a substrate or a lead frame; the LSI is electrically connected to an electrode pad portion formed on the substrate or lead frame by the wire bonding method as described in (3); and its periphery is sealed by a molding resin.

(6) A semiconductor package comprises a semiconductor device equipped with any one of the above-described modes, a substrate disposed opposite to the bonding pad portion of the semiconductor device, a conductive member for electrically connecting the bonding pad of the semiconductor device and the substrate, and further comprises an adhesive between the semiconductor device around the conductive member and the substrate.

It is, for example, a semiconductor package in which at least one LSI having the above-described bonding pad structure has been mounted onto a substrate; an electrode bump is formed at the bonding pad portion on the LSI by the wire bonding method as described in (3) and is electrically connected to an electrode pad portion formed on the substrate; and the electrode bump is sealed at the periphery thereof with an adhesive.

The present invention is preferred, because it exhibits its effect on a semiconductor device which has bonding pads disposed with pitches of 60 mm or less and has an external connection member for LSI having a multilayer interconnection formed using a copper interconnect and a low dielectric constant dielectric material (Low-k material) in combination. The present invention is also preferred, because it exhibits its effect on narrow pitch wire bonding which is conducted at a ratio of a wire diameter to a bonding diameter of bump within a range of ½ or greater. This makes it possible to prevent damage to the pad of the bonding pad portion and improve the bonding property (bonding uniformity).

### BRIEF DESCRIPTION OF THE DRAWINGS

FIG. 1 is a cross-sectional view illustrating a first embodiment of the present invention;

FIG. 2 is a cross-sectional view illustrating a second embodiment of the present invention;

FIG. 3 is a cross-sectional view illustrating a third embodiment of the present invention;

FIG. 4 is a cross-sectional view illustrating a fourth embodiment of the present invention;

FIG. 5 is a cross-sectional view illustrating a fifth embodiment of the present invention;

FIG. 6 is a cross-sectional view illustrating a sixth embodiment of the present invention;

FIG. 7 illustrates the relationship between the diameter of a bonding pad and the shape of a bonding bump;

FIG. 8 illustrates the analysis results of the tensile stress of a barrier metal film as a function of an Al film thickness;

FIG. 9 illustrates the relationship between the bonding property and bonding uniformity as a function of an Al film thickness;

FIG. 10 illustrates the deformation distribution of a bump bonding portion as a function of an Al film thickness;

FIG. 11 illustrates the plastic strain distribution of a bump bonding portion; and

FIG. 12 illustrates the strain distribution of a bump bonding portion in the application direction of ultrasonic vibration and tensile stress distribution of a barrier metal film.

### DETAILED DESCRIPTION OF THE INVENTION

Embodiment of the present invention will hereinafter be described. It is to be noted that the present invention is not limited to the embodiments described herein and can be modified based on the conventionally known art or a technique becoming a known art.

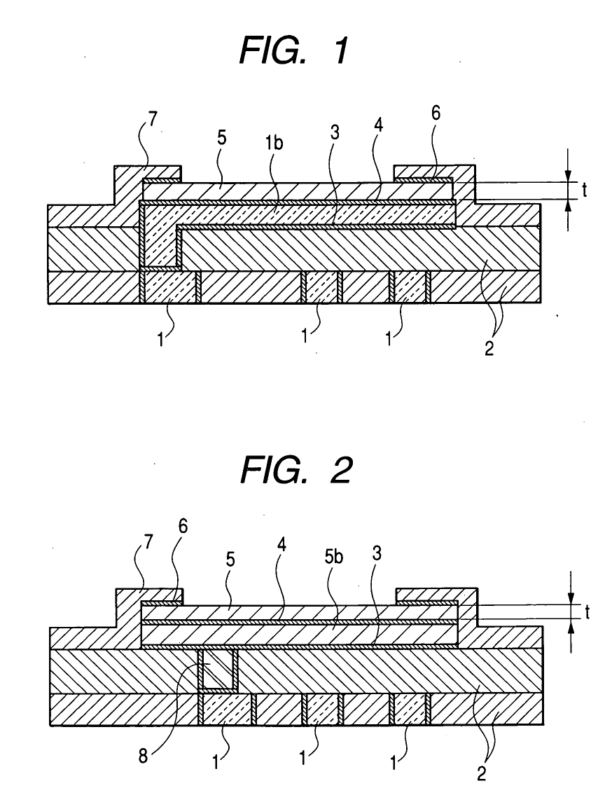

FIG. 1 is across-sectional view of a bonding pad structure on the surface of LSI according to a first embodiment of the present invention. In this embodiment, a description will be made of a connection example between a semiconductor device and an external device via a bonding wire.

An interlayer insulating film made of a dielectric material (SiOC is used here as one example) having a dielectric constant lower than that of SiO is formed on a semiconductor substrate (Si is used here as one example). A plurality of Cu interconnects 1 are formed on the interlayer insulating film. An interlayer insulating film 2 covering the Cu interconnects 1 is then formed on the Cu interconnects 1, followed by the formation of a bonding wiring layer 1b of Cu serving as a bonding pad on the surface of the low dielectric constant (Low-k) insulating film 2. This bonding wiring layer 1b is connected to the Cu interconnects 1 located in the uppermost layer through a via. First, a barrier metal film 3 is formed all over the surface of the insulating film 2, followed by the successive deposition of the Cu bonding interconnect 1b as a main layer of the bonding pad portion, an intermediate metal film 4 as a refractory metal film corresponding to the barrier metal film, and an aluminum alloy film 5. In the end, a cap metal film 6 is formed. The bonding wiring layer 1b has a bonding pad portion and a connection interconnect portion which is formed on the interlayer insulating film and connects the bonding pad portion and the via from the underlying Cu interconnect 1.

As described above, at the bonding pad portion, the aluminum alloy film 5 which is a second layer is disposed, via the intermediate metal film 4, on the bonding interconnect 1b which is a first layer.

The barrier metal film is formed, for example, by depositing, by sputtering, a TiW (titanium tungsten) film, a TiN (titanium nitride) film or a three-layer film having a TiN film sandwiched between Ti films. The barrier metal film or the intermediate metal film containing such a component is preferably disposed below the first layer or the second layer. The film is preferably formed around a region of the second layer to which an external connection member (this means bonding wire here) is bonded, or at an area covered with the final protective film 7. A Cu film is then deposited as a main layer of the bonding pad portion by similar sputtering. A Ti (titanium) film or W (tungsten) film is deposited by sputtering as a refractory metal film corresponding to the barrier metal film, followed by successive deposition of the aluminum alloy film to be used for wire bonding and the cap metal film. The aluminum alloy film which is an upper-layer interconnect of the bonding pad portion having a stacked structure of the Cu film and aluminum alloy film with the refractory metal film, corresponding to the barrier metal film, inserted between them is deposited to give a final thickness (t) of 600 nm or greater but not greater than 1000 nm. The cap metal film 6 which is the uppermost layer, aluminum alloy film 5, refractory intermediate metal film 4 corresponding to the barrier metal film, Cu film 1b and the barrier metal film 3 which is the bottom layer are patterned successively, whereby a stacked interconnection and a bonding pad connected thereto and having the same cross-sectional structure are formed. The above-described patterning is performed by etching with a photo resist film formed by photo lithography as a mask. A final protective film 7 is then formed all over the substrate including the upper surfaces of the stacked interconnect and bonding pad. This protective film is formed on the bonding wiring layer 1b and has an opening portion at the bonding pad portion. As this final protective film, a silicon nitride film deposited, for example, by plasma CVD is used. A resin film is then formed all over the substrate including this final protective film. A polyimide resin is used for this rein film and it is formed with a thickness of from 2 to 10 mm. The resin film and final protective film are then patterned to form an opening portion corresponding to the bonding pad region. The cap metal film 6 lying on the bonding pad and being exposed from the opening portion is removed by etching. By this etching process, the final thickness (t) of the aluminum alloy film of the final bonding pad portion is adjusted to be 600 nm or greater but not greater than 1000 nm. For this etching, plasma etching, for example, with a CF₄ gas is employed.

As described above, the bonding pad portion is equipped with the Cu bonding interconnect 1b which is electrically connected to a wiring layer existing at the top, and the Al alloy film 5 which is a second layer formed on the first layer, and the second layer has a modulus of elasticity higher than that of the first layer.

Even if an external connection member is bonded to a semiconductor device having a Cu interconnect equipped with a low-k interlayer insulating film, the second layer upon bonding can be selectively deformed in accordance with the deformation of underlying first layer so that the stress applied upon bonding can be lowered and an influence on the bonding pad or peripheral structure thereof can be lowered. In this manner, the bonding property can be improved.

Moreover, in this Embodiment, the bonding pad portion is preferably equipped with the first layer, the second layer formed on the first layer, and a third layer (intermediate metal film 4) as an intermediate layer formed between the first layer and the second layer. The third layer has a modulus of elasticity higher than that of each of the first layer and the second layer. It is preferred that as described above, a bonding pad portion has a multilayer structure composed of the first layer connected to an inner interconnect, the third layer formed on the first layer and the second layer formed on the third layer and the third layer is formed to have the highest rigidity (modulus of elasticity) and the second layer is formed to have a rigidity (modulus of elasticity) higher than that of the first layer.

Based on the above-described viewpoint, the Al alloy film 5 which is the second layer can be made thinner than that of the bonding wiring layer 1b which is the first layer and is also a finally stacked wiring layer. This makes it possible to improve the ON characteristics of the Cu wiring layer and improve the rigidity.

Based on another viewpoint, the Al alloy layer 5 which is the second layer can be made thicker than the bonding wiring layer 1b which is the first layer and is also the finally stacked wiring layer. This makes it possible to miniaturize the Cu wiring layer and thereby form a pad portion near a semiconductor element such as transistor. Such a constitution is desired for fabricating a compact semiconductor device having a pad portion located in an active area.

As a specific embodiment, the bonding interconnection is composed mainly of copper; and at the bonding pad portion, an intermediate layer is formed on the bonding pad wiring layer; and a bonding layer composed mainly of aluminum is formed on the intermediate layer.

From the viewpoint of improving efficiency of production steps, the interlayer insulating film between the Cu wiring layer 1 and the bonding pad may be a insulating film having a dielectric constant lower than that of SiO.

From the viewpoint of making a pad portion resistant to stress upon connection of an external connection member, the interlayer insulating film may be a insulating film (SiO) having a dielectric constant lower than that of the interlayer insulating film (for example, SiOC) formed on which the Cu wiring layer 1 has been formed.

The above-described embodiments thus provide a semiconductor device which is equipped with a stacked interconnection structure using Cu/Low-k material, causes less damage to the bonding pad or members around it, and exhibits less deterioration in the bonding property compared with LSI having an aluminum interconnect.

The semiconductor device having a multilayer interconnection formed of a Cu interconnect/Low-k insulating film material can be attained by the bonding pad structure in which all the wiring layers including the uppermost cap interconnect are made of Cu; and the bonding pad portion made of the Cu layer has a refractory intermediate metal layer such as a Ti (titanium) film or (tungsten) film formed on the Cu layer, and an aluminum alloy layer formed on the intermediate metal layer. Characteristics of another bonding pad structure—in which only the uppermost cap wiring layer is made of an aluminum alloy layer; and the bonding pad portion made of the aluminum alloy layer has a refractory intermediate metal layer made of Ti film or the like formed on the aluminum alloy layer, and an aluminum alloy layer formed on the intermediate metal layer—will next be described.

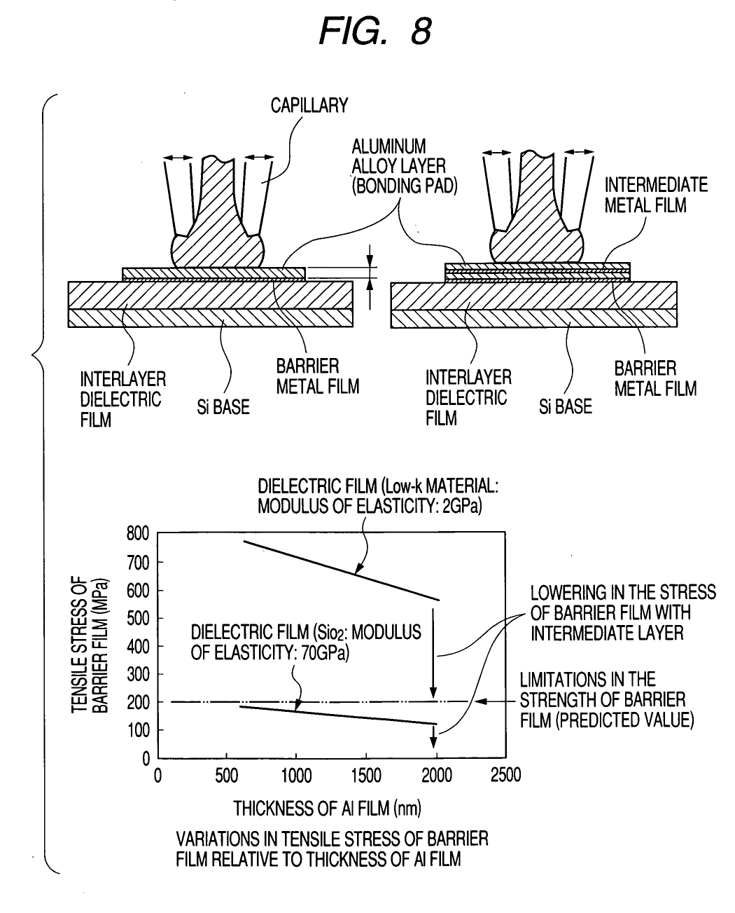

FIG. 8 shows, as a function of thickness of the aluminum alloy film of the bonding pad portion, the maximum tensile stress occurring in a barrier metal film which lies under an aluminum alloy film of a bump bonding portion. The tensile strength of each of a conventional interlayer insulating film made of SiO (modulus of elasticity: about 70 to 80 GPa) and an interlayer insulating film made of a Low-k material having a low dielectric constant is illustrated. The graph shows that the thinner the aluminum alloy film, the greater the tensile stress of the barrier metal film; and that when the interlayer insulating film is a conventional one made of SiO, a stress close to the breaking strength of the barrier metal film is generated at a thickness less than 600 nm, while when a low-elasticity Low-k material is used for the interlayer insulating film, the tensile stress occurring in the barrier metal film is higher by at least 4 times at the maximum at the same thickness with the aluminum alloy film, which inevitably damages the bonding pad portion. As a means for avoiding such damage, found is a method of attaining both bonding uniformity and reduction in the stress of an underlying barrier metal layer by forming an intermediate layer such as Ti film, as a refractory metal film corresponding to the barrier metal film for the aluminum alloy film of the bonding pad portion, and thereby reinforcing the film quality of the bonding pad portion. In the diagram, an arrow shows the degree of reduction in the maximum tensile stress, when a Ti film is formed for example as the intermediate metal film, occurring in the barrier metal film formed on the Low-k material, that is, a material having a low dielectric constant, compared with the maximum tensile stress occurring when the intermediate metal layer is not formed. As is apparent from the diagram, a marked effect for reducing the stress appears even if the Low-k material (modulus of elasticity: 2 GPa) is employed.

In the above-described bonding pad structure, the thickness of the aluminum alloy layer formed as the uppermost layer is preferably adjusted to 600 nm or greater but not greater than 1000 nm.

In the specific embodiment of the bonding pad structure of a semiconductor device having a multilayer interconnection comprising a copper interconnect and a low dielectric constant dielectric material, only the final wiring layer which will be a bonding pad is formed of an aluminum alloy layer via a refractory metal plug; a refractory intermediate metal film is formed on the aluminum alloy layer; and an aluminum alloy layer having a thickness of 600 nm or greater but not greater than 1000 nm is formed on the intermediate metal film.

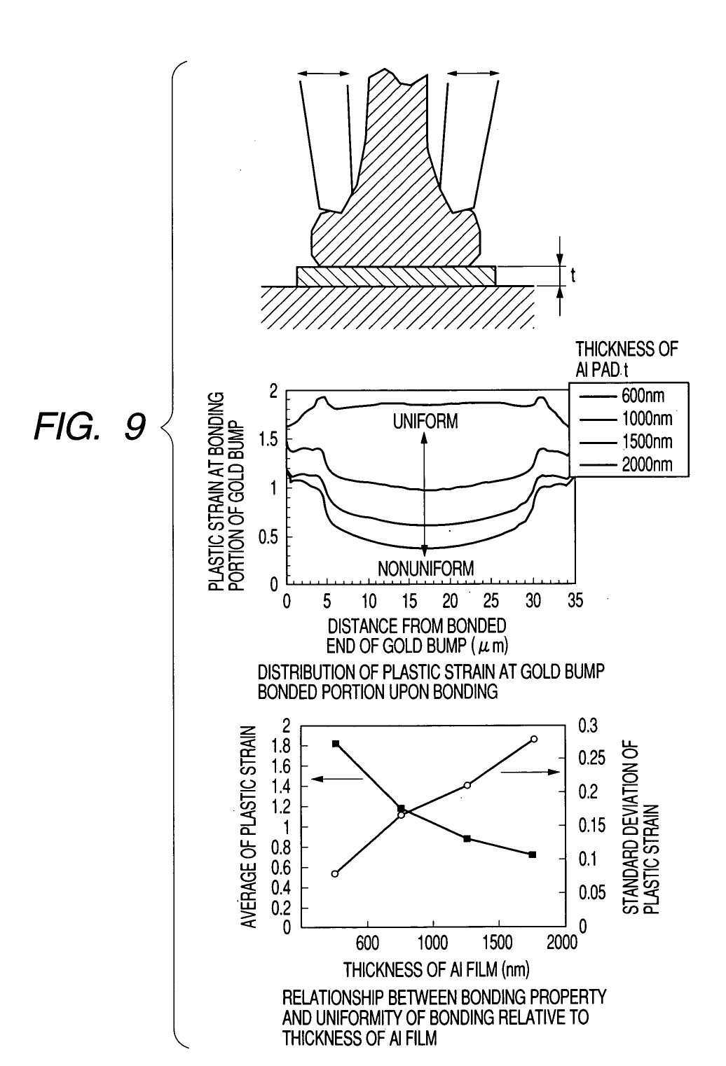

FIG. 9 illustrates a plastic strain distribution of a bump bonding portion as a function of thickness of the aluminum alloy film of the bonding pad portion. As an index for evaluating the bonding property, it is assumed that as the plastic strain on the bump bonding interface is greater, ultrasonic vibration applied from a capillary causes sliding deformation on the interface and promotes the formation of an alloy layer due to thermal diffusion. It has been understood based on this assumption that when the aluminum alloy film of the bonding pad portion is thin (600 nm), a plastic strain distribution is substantially uniform all over the interface, but an increase in the thickness of the aluminum alloy film not only deteriorates the absolute value of plastic strain on the whole but lowers the plastic strain on the inner circumferential side and thereby deteriorates the bonding property on the inner circumferential side. Particularly when the thickness of the aluminum alloy film exceeds 1000 nm, the standard deviation of the plastic strain exceeds the average of the plastic strain and non-uniform bonding is accelerated further.

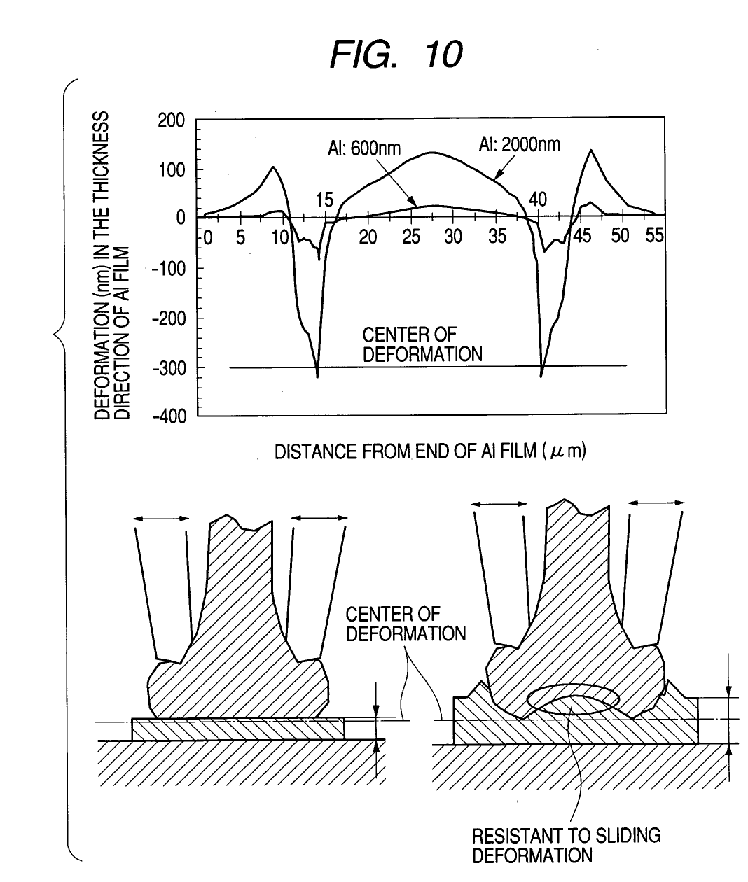

FIG. 10 illustrates a deformation distribution in the thickness direction of the bump bonding portion as a function of thickness of the aluminum alloy film of the bonding pad portion. It has been found that when the aluminum alloy film becomes thick, the bonding interface sinks inside of the aluminum alloy film by the pressing load from the capillary and a deformation center on the inner circumferential side of the bump bonding interface transfers from the bonding interface of the bump to the inside of the aluminum alloy film. This suggests that thinning of the aluminum alloy film is effective for uniform bonding of a bump. As illustrated in FIG. 8, however, the strength of the barrier metal film just below the aluminum alloy layer approaches its limit when the thickness of the aluminum alloy layer decreases to less than 600 nm. In consideration of this fact and also the possibility of a shortage in Al supply upon formation of the alloy layer, which will otherwise lead to disturbance of the formation of the alloy layer, the film thickness of at least 600 nm is necessary. A thickness range capable of attaining both the bonding uniformity and stress reduction of the barrier metal film underlying the aluminum alloy film of the bonding pad portion is judged as an appropriate range. It is needless to say that within this appropriate range, similar effects can be expected even in the conventional wire bonding pad structure made of a single Al film layer. Particularly, in the wire bonding pad having a multilayer structure which is dealt with by the present invention, since the pad structure has already been reinforced by the intermediate metal film, it is possible to adjust the thickness of the uppermost Al film to fall within a range of from 600 nm to 800 nm and give priority only to the uniform bonding.

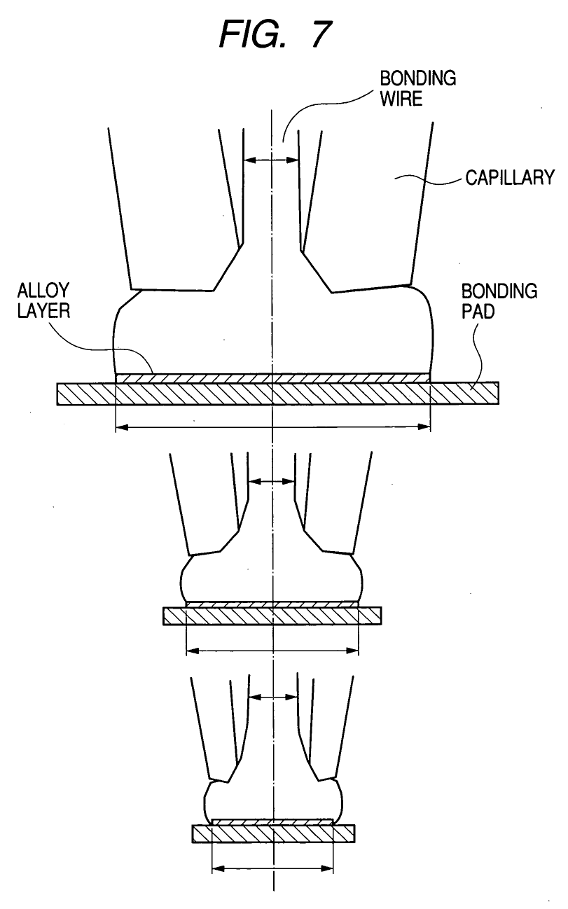

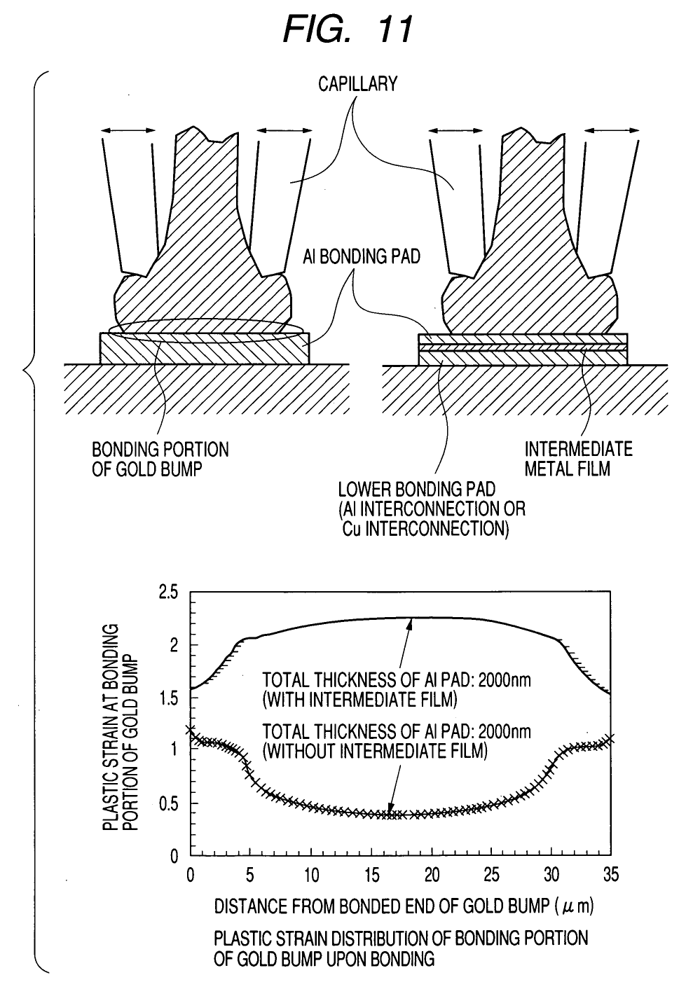

FIG. 11 illustrates the plastic strain distribution of the bump bonding portion when the total thickness of the bump bonding pad is adjusted to 2000 nm; and the bonding pad is formed alone of an aluminum alloy layer or of the aluminum alloy layer and intermediate metal film. The conductor resistance of an aluminum alloy layer is greater than that of copper so that particularly when LSI has a Cu interconnect and a bonding pad which is a final wiring layer is made of the aluminum alloy layer, the aluminum alloy layer has preferably a thickness as great as possible from the viewpoint of electrical properties. Formation of the bonding pad from a thick single layer however accelerates non-uniform bonding as illustrated in FIG. 9. By forming an intermediate metal layer in the bonding pad as illustrated in the diagram, adjusting the thickness of the aluminum alloy layer on the intermediate metal layer within an appropriate range as described above and defining the thickness of the lower aluminum alloy layer from the viewpoints of electrical properties in consideration of the total thickness of the bonding pad, it is possible not only to reduce the damage to the underlying pad as illustrated in FIG. 7 but also to attain the other two objects, that is, uniform bonding and improvement in electrical properties. The lower wiring layer of the bonding pad may be made of either an aluminum alloy layer or Cu interconnect. Use of the copper interconnect however makes conductor resistance smaller and rigidity higher, which enables film thinning compared with the use of an aluminum alloy.

In the wire bonding pad having a three layer structure, the intermediate layer which is the second layer can be thinned while having the highest rigidity (modulus of elasticity), and the bottom layer which is the first layer can be thinned while having a higher rigidity (modulus of elasticity) than that of the top layer which is the third layer.

The rigidity (modulus of elasticity) of each layer is determined by a measuring apparatus such as nanoindenter.

This embodiment is suited for a device fabricated using an interconnection process as minute as 0.18 mm or less and equipped with a Cu interconnect and a Low-k material having a dielectric constant lower than that of silicon.

FIG. 2 is a cross-sectional view of a bonding pad structure on LSI according to a second embodiment of the present invention. The embodiment fundamentally similar to that of Embodiment 1 can be employed here. The final wiring layer which will be a bonding pad is formed of an aluminum alloy layer 5b via a W (tungsten) plug 8 from a final Cu wiring layer 1. Only the interlayer insulating film formed around the W plug located on the Cu wiring layer 1 is not necessarily be made of a material having a low dielectric constant (dielectric constant of 1 or greater but not greater than 3.5) and instead of it, an oxide film such as SiO (dielectric constant of 4 or greater) may be employed. As in Embodiment 1, a refractory metal film 4 corresponding to the barrier metal film and an aluminum alloy film 5 are deposited successively on the aluminum alloy layer, followed by the formation of a cap metal film 6. Also in this case, the aluminum alloy film 5 which is an upper-layer interconnect of the bonding pad portion having a stacked structure of the aluminum alloy films 5 and 5b having therebetween the refractory metal film 4 corresponding to the barrier metal film is formed by deposition to give a final thickness of 600 nm or greater but not greater than 1000 nm. Patterning is then effected and bonding pad portion is formed, as in Embodiment 1.

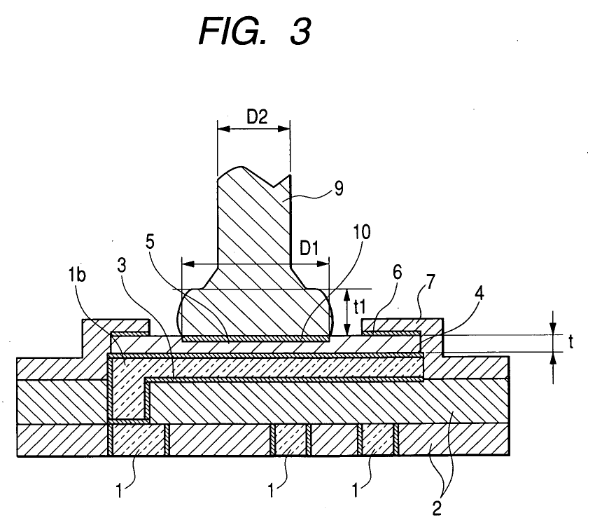

FIG. 3 is a cross-sectional view illustrating a bonding pad structure on LSI according to a third embodiment of the present invention and a bonding wire bonded onto a bonding pad. Wire bonding is fundamentally performed onto the bonding pad portion on LSI formed by the process as described in the first or second embodiment.

In this embodiment, some of the portions bonded via a bonding wire are bonded at a ratio of a bonding height of a bump (thickness) to a bonding diameter of a bump within a range of ⅕ or greater but less than ⅖ and some of them are bonded at this ratio ranging from ⅖ or greater but not greater than ½. More than half of these portions are bonded at a latter ratio, that is, ⅖ or greater but not greater than ½.

After a gold ball at the end of the bonding wire 9 is molten by a torch current, the molten gold ball is pressed onto the bonding pad under a predetermined load by a bonding tool called “capillary”. At the same time, ultrasonic waves of from 60 kHz to 120 kHz are applied, whereby an Au—Al alloy layer 10 is formed by the mutual thermal diffusion phenomenon of the gold ball and aluminum alloy film. There are a number of bonding parameters influencing on the bonding state upon bonding, for example, a capillary shape. In this embodiment, by adjusting a bonding parameter to an appropriate level, the wire bonding conditions are determined so that a ratio (aspect ratio of bump) of a bonding height (t1) of bump to a bonding diameter (D1) of bump in the final bump shape after completion of bonding will be ⅖ or greater but not greater than ½. As a result, in the actual shapes of the bonded wires, some bonding wires are bonded at a ratio of a bonding height of a bump (thickness) to a bonding diameter of a bump ranging from ⅕ or greater but less than ⅖ and some are bonded at the ratio of ⅖ or greater but not greater than ½. Most of them are bonded at the latter ratio, that is, a ratio ranging from ⅖ or greater but not greater than ½. The bonding diameter is defined as an average diameter of a region in which the alloy layer 10 is formed at the center of the bonding cross-section, while the bump height is determined by an average thickness of the bonding bump at the center of the bonding cross-section. It is effective to use a gold alloy wire having a bonding wire diameter (D2) of 20 μm or less for actualizing a narrow pitch bonding wire having a ratio of a bonding diameter (D1) to a wire diameter (D2) within a range of ½ or less (for example, a wire having a diameter of 20 μm and a bonding diameter (D1) of 4 μm or less).

Upon wire bonding, an Au wire, for example, is bonded to a bonding pad portion by a bonding tool called capillary. Bonding is accomplished by applying ultrasonic waves to an initial ball (air ball), which has been formed by melting of a wire end portion at a torch current, while pressing it against the bonding pad portion at 150° C. to 250° C. to form an alloy layer through thermal diffusion of Al of the bonding pad portion and Au wire. The distance between center lines of two adjacent bonding pads is usually called pitch. The dominant bonding pitch has so far been 60 mm or greater, but with recent technical trends in high density packaging of semiconductor chips, a narrow pitch less than 60 mm will soon be used in practice. In the bonding at a pitch narrower than 60 mm, so called “small ball bonding” which uses for bonding an initial ball having a diameter as small as 45 mm or less will be performed. The small ball bonding attains a bonding strength to some extent, but the ball bonded by pressing is sometimes out of round and is deformed severely in a certain direction. Under the recent tendency to narrow pitches, balls bonded to the adjacent two electrodes, respectively happen to be brought into contact each other and cause a short circuit. With a view toward overcoming the above-described problem, the invention as disclosed in Japanese Patent Laid-Open No. 2002-110729 has proposed amethodof using a bonding wire for packaging a semiconductor device which wire contains one or more elements selected from Ca, Be, noble metal elements and rare earth elements in total amounts of from 20 to 1000 wt.ppm and Au and inevitable impurities as the remaining portion; and attaching the bonding wire to an electrode on a semiconductor part after forming, at the end of the wire, an initial ball having a diameter 1 to 1.3 times as much as the CD diameter of the capillary used for bonding. According to the description in it, the invention makes it possible to miniaturize the crystal grains of the initial ball and thereby attains isotropic deformation of the initial ball.

Moreover, bonding at apitchnarrower than 60 mm may involve such a problem as a drastic decrease of a bonding margin. A relationship between the bump shape and capillary tool for bonding the bump when a wire bonding pitch is narrowed is illustrated in FIG. 7. As is apparent from the diagram, when the bonding pads are connected at a wide pitch, force (pressing load+ultrasonic vibration) from the capillary can be transmitted sufficiently to the bump bonding interface, because the bump bonding diameter can be enlarged relative to the wire diameter; but as the pitch becomes narrower, a difference between the wire diameter and the bump bonding diameter decreases and the force from the capillary is transmitted only partially to the bump bonding interface (particularly, the force is not transmitted to the interior side of the bonding interface). When the wire diameter is decreased in proportion to narrowing in the bonding diameter, the rigidity of the wire lowers, the wire flow occurs upon resin molding and electrical short-circuit tends to occur between wires. The wire cannot therefore be narrowed without limitation. Owing to the narrowing in the pitch of the wire bonding, the force from the capillary acts only partially, making it considerably difficult to attain uniform bonding of the whole bonding interface compared with the conventional wire bonding, and also causing another problem that the partial application of the load from the capillary easily breaks the bonding pad.

The above-described problems can be overcome by the above-described embodiment.

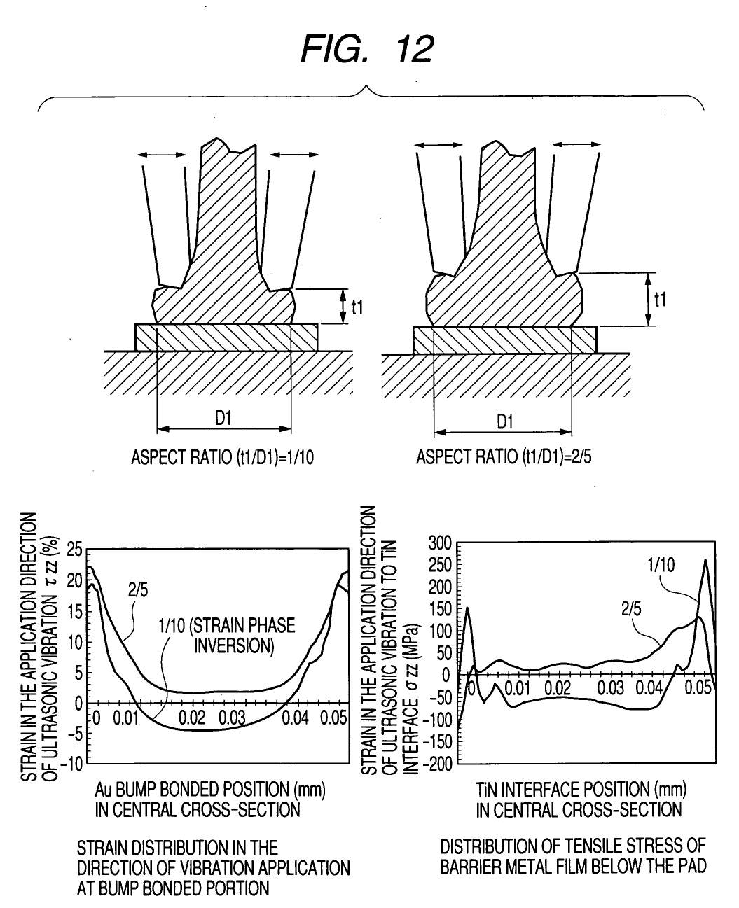

FIG. 12 illustrates the strain distribution in the cross-section of the bump bonding portion in the application direction of ultrasonic vibration and tensile strength distribution generated in the underlying barrier metal film, when the bump height after bonding is set at 5 mm and 20 mm, respectively while fixing the bonding diameter of a bump at 50 mm. From the diagram, it has been found that when the bump height after bonding is 5 mm (aspect ratio: 1/10), phase inversion between the inner circumferential side and outer circumferential side of the bump bonding interface occurs. Described specifically, on the outer side of the bonding interface, deformation occurs so as to extend in the outer circumferential direction, while on the inner circumferential side, deformation occurs so as to shrink in the central direction so that no sliding deformation occurs on the bonding interface at the phase inversion position and a high tensile stress occurs in the bonding pad portion. When the bump height after bonding is 20 mm (aspect ratio: ⅖), on the otherhand, no phase inversion of strain occurs and deformation occurs in a uniform direction relative to the bonding center. It has been found that this enables uniform bonding to the bonding interface and at the same time, enables low-stress bonding to the bonding pad portion so that the latter aspect ratio is effective for reducing the damage to the bonding pad portion. The aspect ratio however cannot be adjusted physically to ½ or greater by the process of pushing down the spherical initial ball and causing sliding of it so that the above-described range is judged appropriate. In the actual wire bonding process, bump shapes do not always perfectly conform to the designed shape. Uniform and low-stress bonding can therefore be attained when some of the wire bonded bumps have a ratio of a bonding height (thickness) of bump to a bonding diameter of bump within a range of ⅕ or greater but less than ⅖ and some of the wire bonded bumps have the ratio within a range of ⅖ or greater but not greater than ½; and most of the wire bonded bumps have a ratio within a range of ⅖ or greater but not greater than ½.

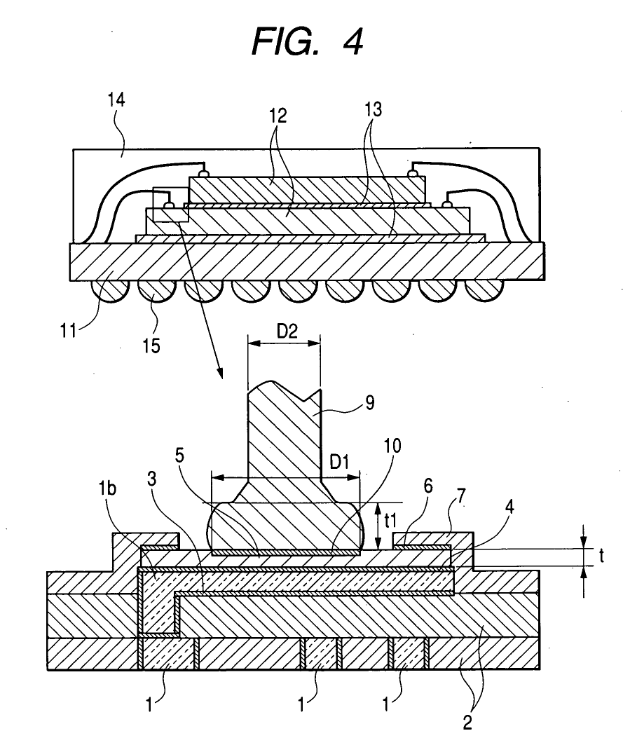

FIG. 4 is across-sectionalviewof asemiconductorpackage structure showing the fourth embodiment of the present invention. This structure is a package structure called BGA (Ball Grid Array). It is formed, first by stacking and adhering LSI chips 12 on an LSI mounting substrate 11 with an adhesive material 13 and electrically connecting, through each wire bonding, a bonding pad portion formed on each LSI and a bonding pad on the side of the LSI mounting substrate. The wire bonding of at least one LSI is conducted for an LSI having a bonding pad structure as described in Embodiment 1 or Embodiment 2. An example of the LSI having a bonding pad structure as shown in the second embodiment is illustrated in this diagram. The whole LSI including a bonding region by wire bonding is then sealed with a molding resin 14 and in the end, solder balls 15 are mounted on the reverse side of the LSI mounting substrate 11.

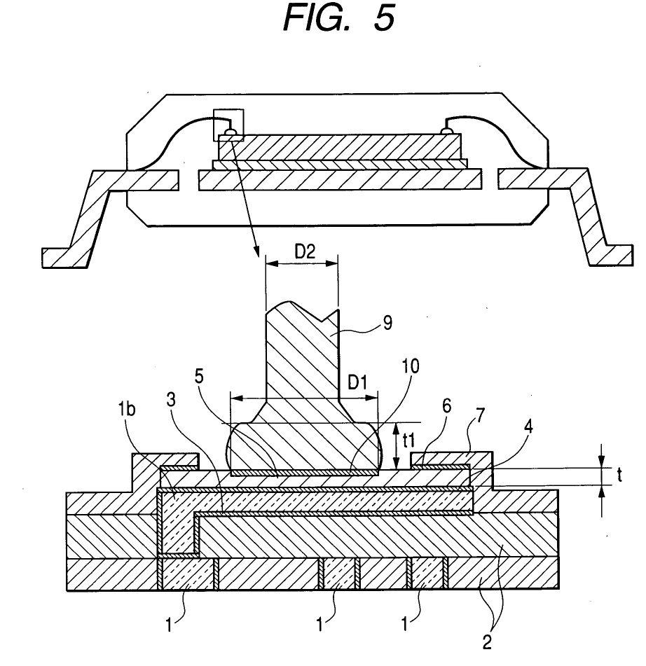

FIG. 5 is across-sectional view of a semiconductor package structure illustrating the fifth embodiment of the present invention. Its package structure is called “QFP” (Quad Flat Package). First, an LSI chip 12 is adhered onto a chip pad 16 formed in a lead frame plane and the bonding pad portion formed on the LSI chip is then electrically connected to the end portion of an inner lead 17 formed in the lead frame plane through wire bonding. The above-described wire bonding is conducted for an LSI having a bonding pad structure as described in the first or second embodiment. The whole LSI including the region bonded by wire bonding and the inner lead region are sealed with a molding resin 14, followed by the formation of an outer lead portion 18 by a mold.

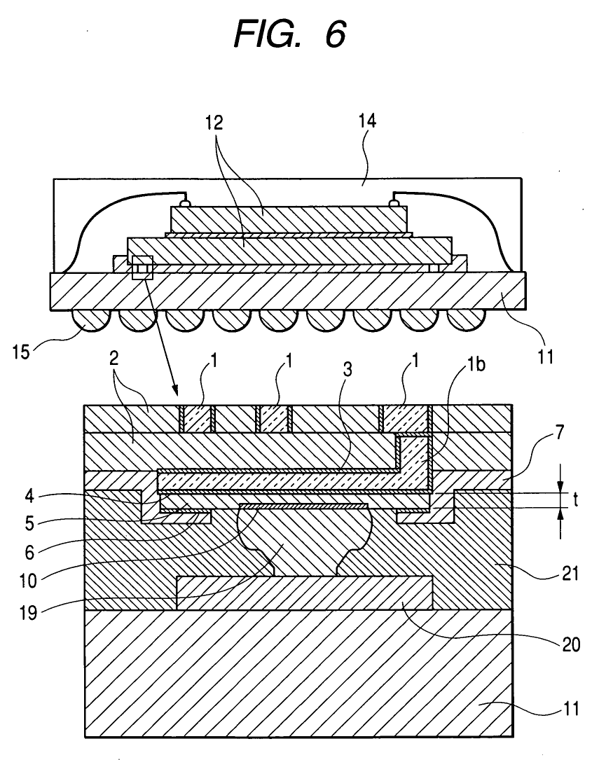

FIG. 6 is across-sectional viewof asemiconductorpackage structure according to the sixth embodiment of the present invention. The outer shape of the package is similar to that having a package structure called “BGA” shown in the fourth embodiment, but the first-level LSI chip 12 stacked on the LSI mounting substrate 11 is bonded not by wire bonding but by a method generally called “flip chip packaging” in which the LSI chip is connected directly to an electrode pad 20 on the LSI mounting substrate side via a connection member (for example, gold bump) 19 formed on the bonding pad portion on LSI. The gold bump can be formed by either one of the stud bump method and plating bump method, but the former one is ordinarily employed, because the gold bump can be formed at a low cost in a manner similar to that employed for wire bonding. The wire bonding pad having a stud bump formed thereon has the bonding pad structure as shown in the first or second embodiment. The flip chip packaging includes a metallurgical bonding system by which ametal bonded surface is formed as in the solder bonding and a non-metallurgical bonding system in which no such surface is formed. In the non-metallurgical bonding system, a load of contact bonding applied to an adhesive material 21 under high temperature causes curing and thermal shrinkage of the adhesive material 21 and a contact pressure appears between the gold bump 19 formed on the LSI chip and an electrode pad 20 on the substrate side, whereby electrical connection between them is attained. Accordingly, particularly in the LSI having a multilayer interconnection made of a Cu interconnect and a low-dielectric-constant dielectric material, the bonding pad structure shown in the first embodiment is effective for preventing pad damage upon pressure bonding.

As described above, the bonding pad structures disclosed in the above-described embodiments facilitate narrow-pitch wire bonding of an LSI having a multilayer interconnection structure composed of a Cu interconnect and a low-dielectric-constant insulating film. In addition, since the thickness of an aluminum alloy layer appropriate for actualizing uniform bonding is defined, highly reliable bonding canbeformed. Withatendencytowardnarrow-pitchwirebonding, an increase in a load onto a thin film portion lying under the bonding pad is inevitable. By forming a bump bonding portion having a proper structure in accordance with the disclosure of the present invention, however, the damage to the underlying film can be reduced and narrow pitch bonding which impairs neither uniform bonding nor reduction in the damage to the underlying film can be attained.

This makes it possible to provide a highly reliable semiconductor device.

According to the present invention, a semiconductor device having a Cu interconnection structure, which causes less damage to an external connection pad or a member around it, and exhibits less deterioration in bonding property compared with an LSI having an aluminum interconnect can be provided.

1. A semiconductor device comprising an external connection pad portion which is connected to a wiring layer having copper as a main component and is electrically connected to the outside, wherein
the wiring layer is formed on a first interlayer insulating film having a dielectric constant lower than that of SiO,
a second interlayer insulating film is formed on the wiring layer and the external connection pad is formed on the second interlayer insulating film, and
the external connection pad has a first layer and a second layer formed thereon,
wherein the second layer has amodulus of elasticity higher than that of the first layer.

2. The semiconductor device according to claim 1, wherein the first layer is thicker than the second layer.

3. A semiconductor device comprising a bonding pad portion which is connected to a wiring layer having copper as a main component and is electrically connected to the outside, wherein
the wiring layer is formed on a first interlayer insulating film having a dielectric constant lower than that of SiO,
a second interlayer insulating film is formed on the wiring layer and the bonding pad portion electrically connected to the wiring layer is formed on the second interlayer insulating film, and
the bonding pad portion has a first layer electrically connected to the wiring layer, a second layer formed on the first layer and a third layer formed between the first and second layers,
wherein the third layer has a modulus of elasticity higher than that of the first layer and the second layer, and the first layer has a modulus of elasticity higher than that of the second layer.

4. The semiconductor device according to claim 3, wherein the first layer is thicker than the second layer.

5. The semiconductor device according to claim 1, wherein the bonding wiring layer has thereon a protective film having an opening portion at the bonding pad portion.

6. A semiconductor device comprising a semiconductor substrate, a semiconductor element formed thereon, a first insulating film layer formed on the semiconductor element, a wiring layer formed on the first insulating film layer and having copper as a main component, a second interlayer insulating film formed on the wiring layer, a bonding wiring layer formed on the second interlayer insulating film and electrically connected to the wiring layer via a plug formed in the second interlayer insulating film, and a bonding pad portion which is formed on the bonding wiring layer and is to have an external connection terminal bonded to the bonding pad portion,
wherein the first interlayer insulating film has a dielectric constant lower than that of SiO,
the bonding wiring layer has copper as a main component, and
the bonding pad portion has an intermediate layer formed on the bonding wiring layer, and a bonding layer having aluminum as a main component formed on the intermediate layer.

7. The semiconductor device according to claim 6, wherein a bonding wire electrically connected to the outside is bonded to the bonding pad portion.

8. The semiconductor device according to claim 6, wherein the second interlayer insulating film has a dielectric constant lower than that of SiO.

9. A semiconductor device comprising a semiconductor substrate, a semiconductor element formed thereon, a first insulating film layer formed on the semiconductor element, a first wiring layer formed on the first insulating film layer and having copper as a main component, a second interlayer insulating film formed on the first wiring layer, a bonding wiring layer formed on the second interlayer insulating film and electrically connected to the first wiring layer via a plug formed in the second interlayer insulating film, a bonding pad portion formed in the bonding wiring layer, and a bonding wire bonded to the bonding pad portion and electrically connected to the outside,
wherein in a plurality of said structures of the device, some bonding wires are bonded at a ratio of a bonding height (thickness) of a bump to a bonding diameter of a bump falling within a range of ⅕ or greater but less than ⅖ and some are bonded at said ratio falling within a range of ⅖ or greater but not greater than ½; and at the same time, more than half of the bonding wires are bonded at said ratio of ⅖ or greater but not greater than ½.

10. The semiconductor package comprising a semiconductor device as claimed in claim 1, a substrate on which the semiconductor device is to be mounted or a lead frame, and bonding wire for electrically connecting the bonding pad portion of the semiconductor device to the substrate or lead frame, and further comprising a molding resin for sealing the bonding wire.

11. The semiconductor package comprising a semiconductor device as claimed in claim 1, a substrate disposed opposite to the bonding pad portion of the semiconductor device, and a conductive member for electrically connecting the bonding pad portion of the semiconductor device to the substrate, and further comprising an adhesive between the semiconductor device around the conductive member and the substrate.
